(19) United States
(12) Patent Application Publication
(10) Pub. No.: US 2023/0418093 A1
(43) Pub. Date: Dec. 28, 2023

(54) OPTICAL MODULATION DEVICE AND LASER APPARATUS

(71) Applicant: Shphotonics Ltd, Suzhou (CN)

(72) Inventors: Lei SUN, Suzhou (CN); Bing QIU, Suzhou (CN)

(21) Appl. No.: 18/341,259

(22) Filed: Jun. 26, 2023

(30) Foreign Application Priority Data
Jun. 27, 2022 (CN) 202210740285.7

(51) Int. Cl. G02F 1/035; H01S 3/00

(52) U.S. Cl. CPC G02F 1/035; H01S 3/0085; G02F 2202/20; G02F 2202/101

(57) ABSTRACT

An optical modulation device includes a waveguide, a first electrode layer, and a second electrode layer. The waveguide layer includes a waveguide body and a plurality of nano-waveguides embedded in the waveguide body and extending in an extension direction. The first electrode layer is arranged on one side of the waveguide layer and includes a plurality of first electrodes extending along the extension direction and arranged in a one-to-one correspondence with the plurality of nano-waveguides. The second electrode layer is arranged on a side of the waveguide layer facing away from the first electrode layer and includes a plurality of second electrodes extending in the extension direction and arranged in a one-to-one correspondence with the plurality of first electrodes.

### CROSS-REFERENCE TO RELATED APPLICATION

This application claims priority to Chinese Application No. 202210740285.7, filed on Jun. 27, 2022, the entire content of which is incorporated herein by reference.

### TECHNICAL FIELD

The present disclosure relates to the laser technology field and, in particular, to an optical modulation device and a laser apparatus.

### BACKGROUND

A laser device is a device that can emit laser. A pump source, a gain medium, and a resonator are three major functional members of the laser device. The pump source provides a light source for the laser device. The gain medium (i.e., working material) absorbs energy provided by the pump source and amplifies light. The resonant cavity is configured to select the light of certain modes for outputting.

The pump source is used as an energy source and is configured to generate photons to excite the gain medium. The photons emitted by the pump source pump particles in the gain medium from a ground state to a high energy level state to achieve population inversion. Excitation mechanisms include optical excitation (optical pumping), gas-discharging excitation, chemical excitation, and nuclear energy excitation. At present, a high-power semiconductor laser device (LD) is generally used as the pump source, which is mainly configured to complete the conversion from electric energy to optical energy. The gain medium is configured to achieve the population inversion, amplify light, and affect a wavelength of the output laser.

The gain medium can be liquid, gas, or solid. The liquid can be organic solution, the gas can be carbon dioxide, and the solid can be ruby. A fundamental requirement of the gain medium is that photons are generated after the gain medium is excited rather than a photothermal conversion. The particles need to be in a relatively isolated state to allow transition between energy levels. The resonant cavity mainly functions to “store” and “purify” the laser.

The resonant cavity is usually formed by two mirrors, or can be a ring-shaped resonant cavity formed by a coupler. Photons are reflected back and forth between the mirrors to continuously cause stimulated radiation in the gain medium to generate high-intensity laser. Meanwhile, the resonant cavity can make the photon in the cavity have the same frequency/wavelength, phase and propagation direction, and make the laser have good directivity and coherence.

The optical performance of the laser apparatus needs to be improved.

### SUMMARY

Embodiments of the present disclosure provide an optical modulation device, including a waveguide, a first electrode layer, and a second electrode layer. The waveguide layer includes a waveguide body and a plurality of nano-waveguides embedded in the waveguide body and extending in an extension direction. The first electrode layer is arranged on one side of the waveguide layer and includes a plurality of first electrodes extending along the extension direction and arranged in a one-to-one correspondence with the plurality of nano-waveguides. The second electrode layer is arranged on a side of the waveguide layer facing away from the first electrode layer and includes a plurality of second electrodes extending in the extension direction and arranged in a one-to-one correspondence with the plurality of first electrodes. Each of the plurality of second electrodes and a corresponding one of the plurality of first electrodes are configured to apply a modulation voltage to a corresponding one of the plurality of nano-waveguides to change a refractive index of the corresponding one of the plurality of nano-waveguide.

Embodiments of the present disclosure provide a laser apparatus, including a laser emitter and an optical modulation device. The optical modulation device is arranged on a light-emitting side of the laser emitter and includes a waveguide, a first electrode layer, and a second electrode layer. The waveguide layer includes a waveguide body and a plurality of nano-waveguides embedded in the waveguide body and extending in an extension direction. The first electrode layer is arranged on one side of the waveguide layer and includes a plurality of first electrodes extending along the extension direction and arranged in a one-to-one correspondence with the plurality of nano-waveguides. The second electrode layer is arranged on a side of the waveguide layer facing away from the first electrode layer and includes a plurality of second electrodes extending in the extension direction and arranged in a one-to-one correspondence with the plurality of first electrodes. Each of the plurality of second electrodes and a corresponding one of the plurality of first electrodes are configured to apply a modulation voltage to a corresponding one of the plurality of nano-waveguides to change a refractive index of the corresponding one of the plurality of nano-waveguides.

### BRIEF DESCRIPTION OF THE DRAWINGS

FIG. 1 is a schematic cross-sectional diagram of an optical modulation device along a thickness direction and a first direction according to some embodiments of the present disclosure.

FIG. 2 is a schematic cross-sectional diagram of an optical modulation device along direction A-A of FIG. 1 according to some embodiments of the present disclosure.

FIG. 3 is a schematic cross-sectional diagram of an optical modulation device along direction A-A of FIG. 1 according to some embodiments of the present disclosure.

FIG. 4 is a schematic cross-sectional diagram of a laser apparatus along a thickness direction and a light-emitting direction according to some embodiments of the present disclosure.

FIG. 5 is a schematic cross-sectional diagram of a laser apparatus along a thickness direction and a light-emitting direction according to some embodiments of the present disclosure.

FIG. 6 is a schematic cross-sectional diagram of a laser apparatus along a thickness direction and a light-emitting direction according to some embodiments of the present disclosure.

### DETAILED DESCRIPTION OF THE EMBODIMENTS

In the following, some example embodiments are described. As those skilled in the art would recognize, the described embodiments can be modified in various manners, all without departing from the spirit or scope of the present disclosure. Accordingly, the drawings and descriptions are illustrative in nature and not limiting.

In the present disclosure, terms such as “first,” “second,” and “third” can be used to describe various elements, components, regions, layers, and/or parts. However, these elements, components, regions, layers, and/or parts should not be limited by these terms. These terms are only used to distinguish one element, component, region, layer, or part from another element, component, region, layer, or layer. Therefore, a first element, component, region, layer, or part discussed below can also be referred to as a second element, component, region, layer, or part, which does not constitute a departure from the teachings of the present disclosure.

A term specifying a relative spatial relationship, such as “below,” “beneath,” “lower,” “under,” “above,” or “higher,” can be used in the disclosure to describe the relationship of one or more elements or features relative to other one or more elements or features as illustrated in the drawings. These relative spatial terms are intended to also encompass different orientations of the device in use or operation in addition to the orientation shown in the drawings. For example, if the device in a drawing is turned over, an element described as “beneath,” “below,” or “under” another element or feature would then be “above” the other element or feature. Therefore, an example term such as “beneath” or “under” can encompass both above and below. Further, a term such as “before,” “in front of,” “after,” or “subsequently” can similarly be used, for example, to indicate the order in which light passes through the elements. A device can be oriented otherwise (e.g., being rotated by 90 degrees or being at another orientation) while the relative spatial terms used herein still apply. In addition, when a layer is referred to as being “between” two layers, it can be the only layer between the two layers, or there can be one or more intervening layers. In this disclosure, if a light beam encounters a first element and then reaches a second element, the second element is referred to as being downstream the first element or downstream the first element in an optical path, and correspondingly the first element is referred to as being upstream the second element or upstream the second element in the optical path.

Terminology used in the disclosure is for the purpose of describing the embodiments only and is not intended to limit the present disclosure. As used herein, the terms “a,” “an,” and “the” in the singular form are intended to also include the plural form, unless the context clearly indicates otherwise. Terms such as “comprising” and/or “including” specify the presence of stated features, entities, steps, operations, elements, and/or parts, but do not exclude the existence or addition of one or more other features, integers, steps, operations, elements, parts, and/or combinations thereof. As used herein, the term “and/or” includes any and all combinations of one or more of the listed items. The phrases “at least one of A and B” and “at least one of A or B” mean only A, only B, or both A and B.

When an element or layer is referred to as being “on,” “connected to,” “coupled to,” or “adjacent to” another element or layer, the element or layer can be directly on, directly connected to, directly coupled to, or directly adjacent to the other element or layer, or there can be one or more intervening elements or layers. In contrast, when an element or layer is referred to as being “directly on,” “directly connected to,” “directly coupled to,” or “directly adjacent to” another element or layer, then there is no intervening element or layer. “On” or “directly on” should not be interpreted as requiring that one layer completely covers the underlying layer.

In the disclosure, description is made with reference to schematic illustrations of example embodiments (and intermediate structures). As such, changes of the illustrated shapes, for example, as a result of manufacturing techniques and/or tolerances, can be expected. Thus, embodiments of the present disclosure should not be interpreted as being limited to the specific shapes of regions illustrated in the drawings, but are to include deviations in shapes that result, for example, from manufacturing. Therefore, the regions illustrated in the drawings are schematic and their shapes are not intended to illustrate the actual shapes of the regions of the device and are not intended to limit the scope of the present disclosure.

Unless otherwise defined, all terms (including technical and scientific terms) used herein have the same meaning as commonly understood by those of ordinary skill in the art to which this disclosure belongs. Terms such as those defined in commonly used dictionaries should be interpreted to have meanings consistent with their meanings in the relevant field and/or in the context of this disclosure, unless expressly defined otherwise herein.

As used herein, the term “substrate” can refer to the substrate of a diced wafer, or the substrate of an un-diced wafer. Similarly, the terms “chip” and “die” can be used interchangeably, unless such interchange would cause conflict. The term “layer” can include a thin film, and should not be interpreted to indicate a vertical or horizontal thickness, unless otherwise specified.

A semiconductor laser device, also known as a laser diode, is a laser device that uses a semiconductor material as a working material. The semiconductor laser device can be a practical type of laser device. The semiconductor laser device is small and has a long lifetime. The semiconductor can be pumped by being charged with current. An operating voltage and an operating current can be compatible with an integrated circuit. Thus, the semiconductor laser device can be suitable for monolithic integration. In addition, for a semiconductor laser device, current can be directly modulated with a frequency up to GHz to obtain a high-speed modulated laser output. Based on the advantages, the semiconductor laser device can be widely used in aspects such as laser communication, optical storage, optical gyro, laser printing, distance ranging, and radar.

In some embodiments, a metasurface device can be arranged at a light-emitting end surface of the semiconductor laser device. Thus, a shape and a direction of an emitted light beam can be modulated using the metasurface device. Metasurface refers to an artificial two-dimensional material with the sizes of basic structure units smaller than the working wavelengths. The basic structure unit can be a nanostructure unit with a size in the order of nanometers. Metasurface can realize flexible and effective control of the characteristics, such as propagation direction, polarization mode, amplitude, and phase, of electromagnetic waves. Metasurface can also have an ultra-light characteristic.

Embodiments of the present disclosure provide an optical modulation device and a laser apparatus to improve the optical performance of the laser apparatus.

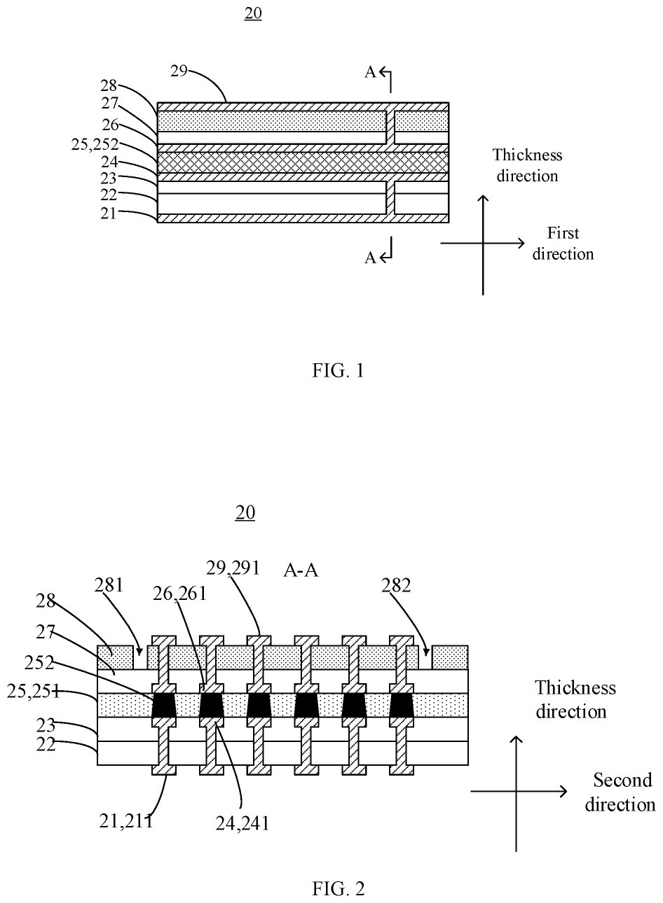

As shown in FIG. 1 and FIG. 2, an optical modulation device 20 of embodiments of the present disclosure includes a waveguide layer 25, a first electrode layer 24, and a second electrode layer 26. The waveguide layer 25 includes a waveguide body 251 and a plurality of nano-waveguides 252 embedded in the waveguide body 251 and extending in a first direction (also referred to as an “extension direction”). The first electrode layer 24 is arranged on one side of the waveguide layer 25 and includes a plurality of first electrodes 241 extending in the first direction and arranged in a one-to-one correspondence with the plurality of nano-waveguides 252. The second electrode layer 26 is arranged on a side of the waveguide layer 25 facing away from the first electrode layer 24 and includes a plurality of second electrodes 261 extending in the first direction and arranged in a one-to-one correspondence with the plurality of first electrodes 241. A second electrode 261 and a corresponding first electrode 241 can be configured to apply a modulation voltage to a corresponding nano-waveguide 252 to change a refractive index of the nano-waveguide 252.

A specific material of the waveguide body 251 is not limited in embodiments of the present disclosure and can include, for example, at least one of silicon, silicon oxide, silicon nitride, gallium arsenide, aluminum gallium arsenide, or indium gallium arsenide. In addition, the waveguide body 251 can also be made of a gain medium material having an amplification effect on optical power, such as doped polycrystalline ceramic.

A width dimension of the nano-waveguide 252 can be smaller than the operating wavelength and in an order of sub-wavelength. In embodiments of the present disclosure, the nano-waveguide 252 can be made of an electro-optical material, which can generate an electro-optical effect. The electro-optic effect refers to that a refractive index of the electro-optical material changes when a voltage is applied to the electro-optical material, which causes a characteristic of a light wave passing through the electro-optical material to change. Through the electro-optical effect, a parameter of an optical signal, such as phase, amplitude, intensity, polarization, beam shape, etc., can be modulated. In embodiments of the present disclosure, the material of the nano-waveguide 252 can include at least one of a lithium niobate crystal, a gallium arsenide crystal, a lithium tantalate crystal, or a potassium dihydrogen phosphate crystal.

In embodiments of the present disclosure, when a modulation voltage is applied to the nano-waveguide 252 of the electro-optical material through the first electrode 241 and the second electrode 261, the refractive index of the nano-waveguide 252 can change as a signal of the modulation voltage changes. Refractive indexes of different nano-waveguides 252 can be flexibly adjusted according to a light-emitting requirement. Thus, the emitted light beam can be actively modulated. For example, deflection, phase, wavelength, intensity, polarization, and/or beam shape, etc., of the emitted light beam can be flexibly modulated. Compared to related technology, the optical performance of the laser apparatus consistent with the disclosure can be improved and expanded.

As shown in FIG. 2, in some embodiments of the present disclosure, the plurality of nano-waveguides 252 are arranged in a single layer and arranged along a second direction (also referred to as an “arrangement direction”) crossing the first direction in sequence, i.e., arranged in one dimension. The second direction can be orthogonal to the first direction or have a determined angle with the first direction. The optical modulation device 20 includes a first wiring layer 21, a substrate 22, a first insulation layer 23, a first electrode layer 24, a waveguide layer 25, a second electrode layer 26, a second insulation layer 27, a cladding layer 28, and a second wiring layer 29, which are arranged and stacked one over another in sequence. The first wiring layer 21 includes a plurality of first wires 211 arranged in a one-to-one correspondence with the plurality of first electrodes 241. Each first wire 211 is connected to a corresponding first electrode 241 through vias in the first substrate 22 and the first insulation layer 23. The second wire layer 29 includes a plurality of second wires 291 arranged in a one-to-one correspondence with the plurality of second electrodes 261. Each second wire 291 is connected to a corresponding second electrode 261 through vias in the cladding layer 28 and the second insulation layer 27. The first wire 211 and the second wire 291 are configured to transmit signals. Specific pattern designs and extension directions of the first wire 211 and the second wire 291 are not limited, e.g., not limited to extending along the first direction.

In some embodiments of the present disclosure, the material of the first electrode layer 24 and the second electrode layer 26 can include at least one of indium tin oxide or indium zinc oxide. In addition, the material of the first wire layer 21 and the second wire layer 29 can also include at least one of indium tin oxide or indium zinc oxide. These materials are transparent and conductive, which can reduce the influence on the light transmission efficiency of the device as much as possible.

In some embodiments, the first wire layer 21 and the second wire layer 29 may also be made of an opaque conductive material, for example, including at least one of aluminum neodymium alloy, aluminum, copper, molybdenum tungsten alloy, or chromium.

The waveguide layer 25 can be prepared as a single layer or can be prepared as a plurality of layers one over another. The plurality of nano-waveguides 252 can be arranged in two dimensions in addition to one dimension. In some embodiments of the present disclosure, the plurality of nano-waveguides can also be arranged in a plurality of layers in the waveguide body. Each layer can include a plurality of nano-waveguides. The plurality of nano-waveguides arranged in the same layer can be arranged along the second direction crossing the first direction in sequence. At least two layers of nano-waveguides do not overlap with each other in a thickness direction. The second direction can be orthogonal to the first direction or have the determined angle with the first direction. With the nano-waveguides arranged in the plurality of layers, the nano-waveguides can achieve a more compact layout, and the modulation efficiency and modulation effect of the light can be enhanced.

As shown in FIG. 2, in some embodiments of the present disclosure, the cladding layer 28 includes a first trench 281 and a second trench 282 extending along the first direction. Orthographic projections of the plurality of first electrodes 241, the plurality of nano-waveguides 252, and the plurality of second electrodes 261 on the substrate 22 are between orthographic projections of the first trench 281 and the second trench 282 on the substrate 22. The cladding layer 28 can cover an outer side of the waveguide layer 25 and can be made of glass or another transparent material having a relatively low refractive index. With the structural design of the cladding layer 28, the light can be limited to propagate in a certain area. In some embodiments of the present disclosure, the design of the first trench 281 and the second trench 282 can guide the light to propagate mainly in the area between the first trench 281 and the second trench 282. Thus, the modulation efficiency of the optical modulation device 20 can be improved.

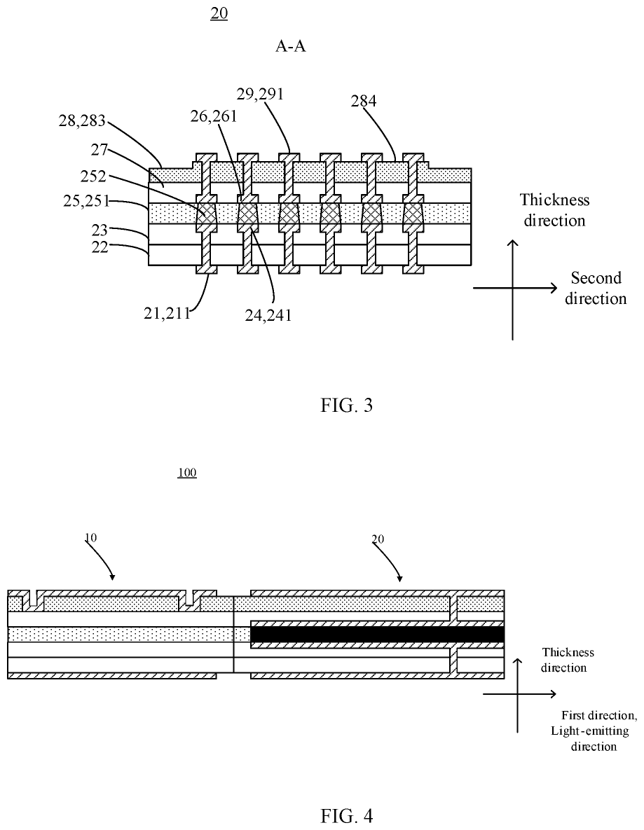

As shown in FIG. 3, in some other embodiments of the present disclosure, the cladding layer 28 also adopts a ridge structural design, including a planar member 283 and a protrusion member 284 arranged on a side of the planar member 283 facing away from the second insulation layer 27. The orthographic projections of the plurality of first electrodes 241, the plurality of nano-waveguides 252, and the plurality of second electrodes 261 on the substrate 22 are within an orthographic projection of the protrusion member 284 on the substrate 22. With the design of protrusion member 284, the light can be limited to propagate within an area guided by the protrusion member 284. Thus, the modulation efficiency of the optical modulation device 20 can be improved.

As shown in FIG. 4, embodiments of the present disclosure also provide a laser apparatus 100, including a laser emitter 10 and the modulation device 20 above arranged on a light-emitting side of the optical modulation device 20. The first direction can be a light-emitting direction of the laser emitter 10.

The laser emitter 10 and the optical modulation device 20 can be cascaded. Structures and electrodes of the laser emitter 10 and the optical modulation device 20 can be configured separately without interference. Since the optical modulation device 20 actively modulates the emitted light beam, the optical performance of the laser device 100 can be flexibly adjusted, expanded, and improved as needed to obtain relatively good optical performance.

Specific type of the laser emitter 10 is not limited. For example, the laser emitter can include a gas laser device, a solid-state laser device, a semiconductor laser device, or a dye laser device. In some embodiments, the laser emitter 10 can be a distributed feedback laser (DFB), with Bragg gratings arranged therein, which is a type of edge-emitting semiconductor laser device. The resonator of the laser emitter 10 can be, for example, a Fabry-Pérot cavity (F-P cavity), which can adjust and control the wavelength.

As shown in FIG. 4, in some embodiments of the present disclosure, the optical modulation device 20 and the laser emitter 10 are fabricated on the same substrate 22. Some structural layers of the optical modulation device 20 can extend to the area where the laser emitter 10 is located, and hence be shared by the optical modulation device 20 and the laser emitter 20. That is, the optical modulation device 20 and the laser emitter 10 can be integrated together. The waveguide body 251 of the optical modulation device 20 can be made of the same gain medium material as the laser emitter 10. Thus, the waveguide body 251 can be prepared in the same layer as the gain medium layer of the laser emitter 10.

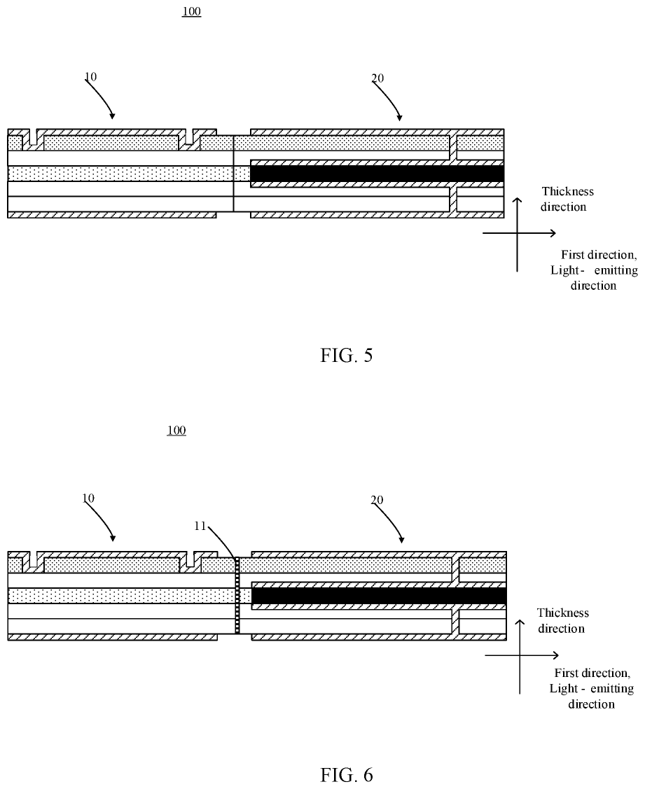

As shown in FIG. 5, in some embodiments of the present disclosure, the optical modulation device 20 and the laser emitter 10 are individual devices. A light-emitting end surface of the laser emitter 10 is directly coupled with the light-incident end surface of the optical modulation device 20. That is, the laser emitter 10 can be directly and optically coupled with the optical modulation device 20 without an intermediate member.

As shown in FIG. 6, in some embodiments of the present disclosure, the optical modulation device 20 and the laser emitter 10 are individual devices. The light-emitting end surface of the laser emitter 10 and the light-incident end surface of the optical modulation device 20 are optically coupled through a lens or a metasurface device 11. The optical adjustment effect of the lens or the metasurface can reduce coupling loss between the optical modulation device 20 and the laser emitter 10 as much as possible.

The present specification provides many different embodiments or examples for implementing the present disclosure. These different embodiments or examples are exemplary and are not used to limit the scope of the present disclosure. Those skilled in the art can think of various modifications or replacements based on the disclosed content of the present disclosure. These modifications and replacements should be within the scope of the present disclosure. Thus, the scope of the present invention is subjected to the scope defined by the appended claims.

What is claimed is:

1. An optical modulation device comprising:
a waveguide layer including a waveguide body and a plurality of nano-waveguides embedded in the waveguide body and extending in an extension direction;
a first electrode layer arranged on a side of the waveguide layer and including a plurality of first electrodes extending along the extension direction and arranged in a one-to-one correspondence with the plurality of nano-waveguides; and
a second electrode layer arranged on a side of the waveguide layer facing away from the first electrode layer and including a plurality of second electrodes extending along the extension direction and arranged in a one-to-one correspondence with the plurality of first electrodes, each of the plurality of second electrodes and a corresponding one of the plurality of first electrodes being configured to apply a modulation voltage to a corresponding one of the plurality of nano-waveguides to change a refractive index of the corresponding one of the plurality of nano-waveguides.

2. The optical modulation device of claim 1, wherein:
the plurality of nano-waveguides are arranged in a single layer and along an arrangement direction crossing the extension direction in sequence.

3. The optical modulation device of claim 1, wherein:
the plurality of nano-waveguides are arranged in a plurality of layers each including two or more of the plurality of nano-waveguides arranged in sequence along an arrangement direction crossing the extension direction, the nano-waveguides in at least two of the plurality of layers not overlapping with each other in a thickness direction of the waveguide layer.

4. The optical modulation device of claim 1,
wherein the plurality of nano-waveguides are arranged in a single layer and along an arrangement direction crossing the extension direction;
the optical modulation device further comprising:
a first wiring layer, a substrate, a first insulation layer, a second insulation layer, a cladding layer, and a second wiring layer;
wherein:
the first wiring layer, the substrate, the first insulation layer, the first electrode layer, the waveguide layer, the second electrode layer, the second insulation layer, the cladding layer, and the second wiring layer are stacked one over another;
the first wiring layer includes a plurality of first wires arranged in a one-to-one correspondence with the plurality of first electrodes and each connected to a corresponding one of the plurality of first electrodes through a via in the substrate and a via in the first insulation layer; and
the second wiring layer includes a plurality of second wires arranged in a one-to-one correspondence with the plurality of second electrodes and each connected to a corresponding one of the plurality of second electrodes through a via in the cladding layer and a via in the second insulation layer.

5. The optical modulation device of claim 4, wherein:
the cladding layer includes a first trench and a second trench extending in the extension direction; and
orthographic projections of the plurality of first electrodes, the plurality of nano-waveguides, and the plurality of second electrodes on the substrate are between orthographic projections of the first trench and the second trench on the substrate.

6. The optical modulation device of claim 4, wherein:
the cladding layer includes a planar member and a protrusion member arranged on a side of the planar member facing away from the second insulation layer; and
orthographic projections of the plurality of first electrodes, the plurality of nano-waveguides, and the plurality of second electrodes on the substrate are within an orthographic projection of the protrusion member on the substrate.

7. The optical modulation device of claim 1, wherein:
a material of the waveguide body includes at least one of silicon, silicon oxide, silicon nitride, gallium arsenide, aluminum gallium arsenide, or indium gallium arsenide.

8. The optical modulation device of claim 1, wherein:
a material of the waveguide body includes a gain medium material.

9. The optical modulation device of claim 1, wherein:
a material of the plurality of nano-waveguides includes at least one of lithium niobate crystal, gallium arsenide crystal, lithium tantalate crystal, or potassium dihydrogen phosphate crystal.

10. The optical modulation device of claim 1, wherein a material of the first electrode layer and a material of the second electrode layer include at least one of indium tin oxide or indium zinc oxide.

11. A laser apparatus comprising:
a laser emitter; and
an optical modulation device arranged on a light-emitting side of the laser emitter and including:
a waveguide layer including a waveguide body and a plurality of nano-waveguides embedded in the waveguide body and extending in an extension direction, the direction being a light-emitting direction of the laser emitter;
a first electrode layer arranged on a side of the waveguide layer and including a plurality of first electrodes extending along the extension direction and arranged in a one-to-one correspondence with the plurality of nano-waveguides; and
a second electrode layer arranged on a side of the waveguide layer facing away from the first electrode layer and including a plurality of second electrodes extending in the extension direction and arranged in a one-to-one correspondence with the plurality of first electrodes, each of the plurality of second electrodes and a corresponding one of the plurality of first electrodes being configured to apply a modulation voltage to a corresponding one of the plurality of nano-waveguides to change a refractive index of the corresponding one of the plurality of nano-waveguides.

12. The laser apparatus of claim 11, wherein:
the optical modulation device and the laser emitter are formed on a same substrate.

13. The laser apparatus of claim 11, wherein:
the optical modulation device and the laser emitter are individual devices, and a light-emitting end surface of the laser emitter is directly and optically coupled with a light-incident end surface of the optical modulation device.

14. The laser apparatus of claim 11, wherein:
the optical modulation device and the laser emitter are individual devices, and the light-emitting end surface of the laser emitter is optically coupled with the light-incident end surface of the optical modulation device through a lens or a metasurface device.

15. The laser apparatus of claim 11, wherein the laser emitter includes a gas laser device, a solid state laser device, a semiconductor laser device, or a dye laser device.

16. The laser apparatus of claim 11, wherein:
the plurality of nano-waveguides are arranged in a single layer and in sequence along an arrangement direction crossing the extension direction.

17. The laser apparatus of claim 11, wherein:
the plurality of nano-waveguides are arranged in a plurality of layers each including two or more of the plurality of nano-waveguides arranged in sequence along an arrangement direction crossing the extension direction, the nano-waveguides in at least two of the plurality of layers not overlapping with each other in a thickness direction of the waveguide layer.

18. The laser apparatus of claim 11,
wherein:
the plurality of nano-waveguides are arranged in a single layer and along an arrangement direction crossing the extension direction;
the optical modulation device further comprising:
a first wiring layer, a substrate, a first insulation layer, a second insulation layer, a cladding layer, and a second wiring layer;
wherein:
the first wiring layer, the substrate, the first insulation layer, the first electrode layer, the waveguide layer, the second electrode layer, the second insulation layer, the cladding layer, and the second wiring layer are stacked one over another;
the first wiring layer includes a plurality of first wires arranged in a one-to-one correspondence with the plurality of first electrodes and each connected to a corresponding one of the plurality of first electrodes through a via in the substrate and a via in the first insulation layer; and
the second lead layer includes a plurality of second wires arranged in a one-to-one correspondence with the plurality of second electrodes, and each connected to a corresponding one of the plurality of second electrodes through a via in the cladding layer and a via in the second insulation layer.

19. The laser apparatus of claim 17, wherein:
the cladding layer includes a first trench and a second trench extending in the extension direction; and
orthographic projections of the plurality of first electrodes, the plurality of nano-waveguides, and the plurality of second electrodes on the substrate are between orthographic projections of the first trench and the second trench on the substrate.

20. The laser apparatus of claim 17, wherein:
the cladding layer includes a planar member and a protrusion member arranged on a side of the planar member facing away from the second insulation layer; and
orthographic projections of the plurality of first electrodes, the plurality of nano-waveguides, and the plurality of second electrodes on the substrate are within an orthographic projection of the protrusion member on the substrate.
